(19) United States
(12) Patent Application Publication
(10) Pub. No.: US 2026/0112408 A1
(43) Pub. Date: Apr. 23, 2026

(54) Multi-die Memory Chip with Individually Connected Data (DQ) Pins

(71) Applicant: Advanced Micro Devices, Inc., Santa Clara, CA (US)

(72) Inventors: Aaron John Nygren, Boise, ID (US); Christopher Edward Cox, Placerville, CA (US); Edoardo Prete, Arlington, MA (US); Anwar Parvez Kashem, Sudbury, MA (US)

(73) Assignee: Advanced Micro Devices, Inc., Santa Clara, CA (US)

(21) Appl. No.: 19/302,374

(22) Filed: Aug. 18, 2025

Related U.S. Application Data
(60) Provisional application No. 63/709,642, filed on Oct. 21, 2024.

(51) Int. Cl. G11C 11/4096; G11C 11/4076; G11C 11/4093; H01L 23/00; H01L 25/065; H10B 80/00

(52) U.S. Cl. CPC G11C 11/4096; G11C 11/4076; G11C 11/4093; H10W 90/00; H10B 80/00; H10W 90/297; H10W 90/722; H10W 90/724; H10W 90/725; H10W 90/752; H10W 90/754

(57) ABSTRACT

A multi-die memory chip with individually accessible data (DQ) pins is described. In one or more implementations, a memory chip includes a plurality of memory die arranged in a stacked configuration, a package substrate, and a plurality of data pins that are individually accessible via corresponding connectors. The memory die may be separated into at least two ranks, with a first subset of the data pins associated with a first rank and a second subset of the data pins associated with a second rank. The individual accessibility of the first and second subsets of data pins enables the memory chip to operate in a multiplexed mode or an error correcting code mode.

### RELATED APPLICATION

This application claims priority to U.S. Provisional Application Ser. No. 63/709,642, filed 21 Oct. 2024, titled “Multi-die Memory Chip with Individually Connected Data (DQ) Pins,” the disclosure of which is incorporated by reference herein in its entirety.

### BACKGROUND

Dual In-Line Memory Modules (DIMMs) are circuit boards that hold dynamic random-access memory (DRAM) chips, which serve as the memory for many computers. Over time, advancements in DIMM technology (e.g., DDR4 to DDR5)—such as increases in speed, higher data transfer rates, and larger storage capacities—have improved computer performance, enabling faster data processing, smoother multitasking, and support for memory-intensive applications like virtual machines, large-scale databases, and artificial intelligence workloads. These innovations can also contribute to energy efficiency, which reduces power consumption while delivering higher performance.

### BRIEF DESCRIPTION OF THE DRAWINGS

FIG. 1 is a block diagram of a processing system configured to execute one or more applications, in accordance with one or more implementations.

FIG. 2 is a block diagram of a non-limiting example of a memory system.

FIG. 3 is a block diagram of a non-limiting example of pins of multiple memory die of a memory chip, such as of a stacked DRAM.

FIG. 4 is a block diagram of a non-limiting example depicting how data (DQ) pins of multiple memory die of a memory chip are directly connected to a package substrate.

FIG. 5 depicts a prior art example of connecting data (DQ) pins of a multi-die memory chip to data package entry points.

FIG. 6 is a block diagram of a non-limiting example depicting how data (DQ) pins of multiple memory die of a memory chip are directly connected to a die serving as a controller for the memory chip.

FIG. 7 is a block diagram of a non-limiting example depicting how data (DQ) pins of multiple memory die of a memory chip are connected to a package substrate with through silicon vias and micro-bumps.

FIG. 8 is a block diagram of a non-limiting example depicting how data (DQ) pins of multiple memory die of a memory chip are connected to a die serving as a controller for the memory chip with through silicon vias and micro-bumps.

FIG. 9 depicts a procedure in an example implementation of a multi-die memory chip with individually connected data (DQ) pins.

### DETAILED DESCRIPTION

In conventional stacked dynamic random-access memory (DRAM) configurations, pairs of data (DQ) pins from memory die having different ranks are connected together, such as by using short bond wires between the memory die. However, this conventional approach can limit flexibility and potential performance.

In such traditional memory systems, for example, including those configured according to DDR5, memory die within a memory chip package (e.g., DRAM) are often interconnected in a manner that restricts access to individual die. This is because the DQ pins of one die are typically connected to the DQ pins of another die, and together they connect to a single external pin. This setup restricts the ability to independently address or manipulate the data paths of individual pins with each data strobe (DQS), which can be a significant limitation in systems requiring high flexibility and performance, such as those used in high-performance computing or advanced data processing applications.

Multi-die memory chips with individually connected data (DQ) pins are described. In contrast with conventional approaches, the described architecture connects each individual data (DQ) pin (e.g., directly) to a package substrate of the memory chip (e.g., the DRAM), a memory die serving as a controller for the memory chip, or externally at the printed circuit board level, e.g., by using long bond wires.

This direct, individual connection scheme for data (DQ) pins enables a variety of benefits. For example, this approach enables increased flexibility in memory access configurations, allowing the memory to be used in a multiplexed (MUX) mode and/or an error correcting code (ECC) mode—rather than using an entire memory chip or memory system for one mode or the other. The described approach can also improve signal integrity by eliminating the need for short bonds between die, which can introduce signal degradation. The flexibility of the described approach can also increase memory bandwidth and improve system performance by allowing separate access to each memory rank within a multi-die package.

In some aspects, the techniques described herein relate to a memory chip, including: a package substrate; and a plurality of memory die arranged in a stacked configuration, the plurality of memory die having a plurality of data pins, wherein the plurality of data pins are individually accessible via connectors to the package substrate or an intermediate controller.

In some aspects, the techniques described herein relate to a memory chip, wherein the connectors are bond wires.

In some aspects, the techniques described herein relate to a memory chip, wherein the connectors include through silicon vias and micro bumps.

In some aspects, the techniques described herein relate to a memory chip, wherein each data pin of the plurality of data pins is individually connected to the package substrate or the intermediate controller via a respective connector.

In some aspects, the techniques described herein relate to a memory chip, wherein the intermediate controller is a memory die of the plurality of memory die configured to control routing of data to and from each of the plurality of data pins individually.

In some aspects, the techniques described herein relate to a memory chip, wherein the memory die is further configured to isolate data signals and handle clocking signals including at least one of data strobe (DQS), write clock (WCK), or clock (CK) signals.

In some aspects, the techniques described herein relate to a memory chip, wherein the plurality of memory die are separated into at least two ranks.

In some aspects, the techniques described herein relate to a memory chip, wherein a first subset of the plurality of data pins is associated with a first rank and a second subset of the plurality of data pins is associated with a second rank.

In some aspects, the techniques described herein relate to a memory chip, wherein the first subset of data pins and the second subset of data pins are individually accessible.

In some aspects, the techniques described herein relate to a memory chip, wherein the intermediate controller is a buffer connectively disposed between the plurality of data pins and the package substrate, and wherein each data pin of the plurality of data pins is connected to the buffer via the connectors and the buffer is connected to the package substrate.

In some aspects, the techniques described herein relate to a memory chip, wherein the buffer is configured to control the plurality of data pins individually to transmit data in association with performing at least one of a read memory access or a write memory access of the plurality of memory die.

In some aspects, the techniques described herein relate to a memory chip, wherein the plurality of data pins are individually controllable by a buffer external to the memory chip to transmit data in association with performing at least one of a read memory access or a write memory access of the plurality of memory die.

In some aspects, the techniques described herein relate to a memory chip, wherein the memory chip is a dynamic random-access memory (DRAM) package and the plurality of memory die are DRAM die.

In some aspects, the techniques described herein relate to a method including: receiving a memory access request for a memory chip including a plurality of memory die arranged in a stacked configuration and having a plurality of data pins individually accessible via connectors to a package substrate or an intermediate controller of the memory chip; and causing data corresponding to the memory access request to be transmitted via at least one data pin of the plurality of data pins and the connectors corresponding to the at least one data pin to service the memory access request.

In some aspects, the techniques described herein relate to a method, wherein the memory access request is a write request.

In some aspects, the techniques described herein relate to a method, further including causing the data corresponding to the memory access request to be transmitted from the package substrate via the connectors corresponding to the at least one data pin and sent on the at least one data pin for writing.

In some aspects, the techniques described herein relate to a method, wherein the memory access request is a read request.

In some aspects, the techniques described herein relate to a method, further including causing the data to be read from a location in the memory chip where the data is stored and sent on the at least one data pin via the connectors corresponding to the at least one data pin to the package substrate.

In some aspects, the techniques described herein relate to a computing system, including: a processor; and a memory system communicatively coupled to the processor to service memory access requests of the processor, wherein the memory system includes a memory chip including: a package substrate; and a plurality of memory die arranged in a stacked configuration, the plurality of memory die having a plurality of data pins, wherein the plurality of data pins are individually accessible via connectors to the package substrate or an intermediate controller.

In some aspects, the techniques described herein relate to a computing system, wherein the memory system is an in-line memory module.

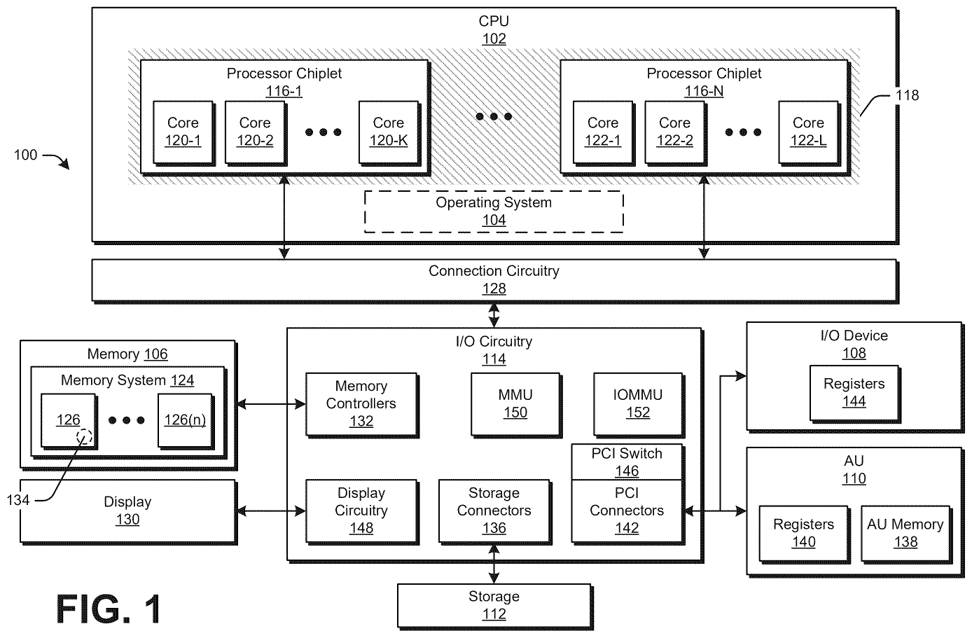

FIG. 1 is a block diagram of a processing system configured to execute one or more applications, in accordance with one or more implementations.

FIG. 1 includes a processing system 100 configured to execute one or more applications, such as compute applications (e.g., machine-learning applications, neural network applications, high-performance computing applications, databasing applications, gaming applications), graphics applications, and the like. Examples of devices in which the processing system is implemented include, but are not limited to, a server computer, a personal computer (e.g., a desktop or tower computer), a smartphone or other wireless phone, a tablet or phablet computer, a notebook computer, a laptop computer, a wearable device (e.g., a smartwatch, an augmented reality headset or device, a virtual reality headset or device), an entertainment device (e.g., a gaming console, a portable gaming device, a streaming media player, a digital video recorder, a music or other audio playback device, a television, a set-top box), an Internet of Things (IoT) device, an automotive computer or computer for another type of vehicle, a networking device, a medical device or system, and other computing devices or systems.

In the illustrated example, the processing system 100 includes a central processing unit (CPU) 102. In one or more implementations, the CPU 102 is configured to run an operating system (OS) 104 that manages the execution of applications. For example, the OS 104 is configured to schedule the execution of tasks (e.g., instructions) for applications, allocate portions of resources (e.g., system memory 106, CPU 102, input/output (I/O) device 108, accelerator unit (AU) 110, storage 112, I/O circuitry 114) for the execution of tasks for the applications, provide an interface to I/O devices (e.g., I/O device 108) for the applications, or any combination thereof.

The CPU 102 includes one or more processor chiplets 116, which are communicatively coupled together by a data fabric 118 in one or more implementations.

Each of the processor chiplets 116, for example, includes one or more processor cores 120, 122 configured to concurrently execute one or more series of instructions, also referred to herein as “threads,” for an application. Further, the data fabric 118 communicatively couples each processor chiplet 116-N of the CPU 102 such that each processor core (e.g., processor cores 120) of a first processor chiplet (e.g., 116-1) is communicatively coupled to each processor core (e.g., processor cores 122) of one or more other processor chiplets 116. Though the example embodiment presented in FIG. 1 shows a first processor chiplet (116-1) having three processor cores (120-1, 120-2, 120-K) representing a K number of processor cores 120 and a second processor chiplet (116-N) having three processor cores (e.g., 122-1, 122-2, 122-L) representing an L number of processor cores 122, in other implementations (L being an integer number greater than or equal to one), each processor chiplet 116 may have any number of processor cores 120, 122. For example, each processor chiplet 116 can have the same number of processor cores 120, 122 as one or more other processor chiplets 116, a different number of processor cores 120, 122 as one or more other processor chiplets 116, or both.

Examples of connections which are usable to implement data fabric include, but are not limited to, buses (e.g., a data bus, a system, an address bus), interconnects, memory channels, through silicon vias, traces, and planes. Other example connections include optical connections, fiber optic connections, and/or connections or links based on quantum entanglement.

In this example, the memory 106 is depicted with memory system 124, which is depicted with memory chips 126. In one or more implementations, the memory system 124 corresponds to a type of memory configured according to a standard, such as according to a JEDEC (Joint Electron Device Engineering Council) standard. Additionally or alternatively, the memory system 124 is a memory module, such as a dual in-line memory module (DIMM). In at least one example, for instance, the memory system 124 is a DIMM configured according to a JEDEC standard applicable to DIMMs, such as according to a double data rate #(DDR #) standard, where the ‘#’ symbol corresponds to an integer. In one or more implementations, the memory chips 126 are dynamic random-access memory (DRAM) chips, which are coupled to a printed circuit board forming the memory system 124. The memory system 124 is depicted with memory chip 126 and memory chip 126(n), where n represents any integer greater than or equal to 1. This represents that the memory system 124 is equipped with multiple memory chips 126 and may include various numbers of the memory chips 126. Although only one memory system 124 is depicted, in one or more implementations, the system 100 may include multiple memory systems 124, such as multiple memory systems 124 arranged in a stacked configuration. Additionally, or alternatively, multiple memory systems 124 arranged in a stack may also be arranged in a stack with one or more compute units, such as with one or more CPUs or GPUs and/or portions of a CPU or GPU, e.g., cores.

Additionally, within the processing system 100, the CPU 102 is communicatively coupled to an I/O circuitry 114 by a connection circuitry 128. For example, each processor chiplet 116 of the CPU 102 is communicatively coupled to the I/O circuitry 114 by the connection circuitry 128. The connection circuitry 128 includes, for example, one or more data fabrics, buses, buffers, queues, and the like. The I/O circuitry 114 is configured to facilitate communications between two or more components of the processing system 100 such as between the CPU 102, system memory 106, display 130, universal serial bus (USB) devices, peripheral component interconnect (PCI) devices (e.g., I/O device 108, AU 110), storage 112, and the like.

As an example, system memory 106 includes any combination of one or more volatile memories and/or one or more non-volatile memories, examples of which include dynamic random-access memory (DRAM), static random-access memory (SRAM), non-volatile RAM, and the like. To manage access to the system memory 106, such as by the CPU 102, the I/O device 108, the AU 110, and/or any other components, the I/O circuitry 114 includes one or more memory controllers 132. These memory controllers 132, for example, include circuitry configured to manage and fulfill memory access requests issued from the CPU 102, the I/O device 108, the AU 110, and/or any other device of the system. Examples of such requests include read requests, write requests, fetch requests, pre-fetch requests, and so on. That is to say, these memory controllers 132 are configured to manage access to the data stored at one or more memory addresses within the system memory 106, such as by CPU 102, the I/O device 108, and/or the AU 110. Although the memory controllers 132 are depicted separate from the memory system 124 in this example, in one or more implementations, one or more such memory controllers are included as part of the memory system 124, e.g., incorporated on or in or otherwise attached to the printed circuit board to which the memory chips 126 are mounted.

When an application is to be executed by processing system 100, the OS 104 running on the CPU 102 is configured to load at least a portion of program code 134 (e.g., an executable file) associated with the application from, for example, a storage 112 into system memory 106, such as into one or more memory chips 126 of the memory system 124. This storage 112, for example, includes a non-volatile storage such as a flash memory, solid-state memory, hard disk, optical disc, or the like, configured to store program code 134 for one or more applications.

To facilitate communication between the storage 112 and other components of processing system 100, the I/O circuitry 114 includes one or more storage connectors 136 (e.g., universal serial bus (USB) connectors, serial AT attachment (SATA) connectors, PCI Express (PCIe) connectors) configured to communicatively couple storage 112 to the I/O circuitry 114 such that I/O circuitry 114 is capable of routing signals to and from the storage 112 to one or more other components of the processing system 100.

In association with executing an application, in one or more scenarios, the CPU 102 is configured to issue one or more instructions (e.g., threads) to be executed for an application to the AU 110. The AU 110 is configured to execute these instructions by operating as one or more vector processors, coprocessors, graphics processing units (GPUs), general-purpose GPUs (GPGPUs), non-scalar processors, highly parallel processors, artificial intelligence (AI) processors (also known as neural processing units, or NPUs), inference engines, machine-learning processors, other multithreaded processing units, scalar processors, serial processors, programmable logic devices (e.g., field-programmable gate arrays (FPGAs)), or any combination thereof.

In at least one example, the AU 110 includes one or more compute units that concurrently execute one or more threads of an application and store data resulting from the execution of these threads in AU memory 138. This AU memory 138, for example, includes any combination of one or more volatile memories and/or non-volatile memories, examples of which include caches, video RAM (VRAM), or the like. In one or more implementations, these compute units are also configured to execute these threads based on the data stored in one or more physical registers 140 of the AU 110. Alternatively, or additionally, the AU 110 includes memory like the memory system 124, e.g., one or more memory modules.

To facilitate communication between the AU 110 and one or more other components of processing system 100, the I/O circuitry 114 includes or is otherwise connected to one or more connectors, such as PCI connectors 142 (e.g., PCIe connectors) each including circuitry configured to communicatively couple the AU 110 to the I/O circuitry such that the I/O circuitry 114 is capable of routing signals to and from the AU 110 to one or more other components of the processing system 100. Further, the PCIe connectors 142 are configured to communicatively couple the I/O device 108 to the I/O circuitry 114 such that the I/O circuitry 114 is capable of routing signals to and from the I/O device 108 to one or more other components of the processing system 100.

By way of example and not limitation, the I/O device 108 includes one or more keyboards, pointing devices, game controllers (e.g., gamepads, joysticks), audio input devices (e.g., microphones), touch pads, printers, speakers, headphones, optical mark readers, hard disk drives, flash drives, solid-state drives, and the like. Additionally, the I/O device 108 is configured to execute one or more operations, tasks, instructions, or any combination thereof based on one or more physical registers 144 of the I/O device 108. In one or more implementations, such physical registers 144 are configured to maintain data (e.g., operands, instructions, values, variables) indicating one or more operations, tasks, or instructions to be performed by the I/O device 108.

To manage communication between components of the processing system 100 (e.g., AU 110, I/O device 108) that are connected to PCI connectors 142, and one or more other components of the processing system 100, the I/O circuitry 114 includes PCI switch 146. The PCI switch 146, for example, includes circuitry configured to route packets to and from the components of the processing system 100 connected to the PCI connectors 142 as well as to the other components of the processing system 100. As an example, based on address data indicated in a packet received from a first component (e.g., CPU 102), the PCI switch 146 routes the packet to a corresponding component (e.g., AU 110) connected to the PCI connectors 142.

Based on the processing system 100 executing a graphics application, for instance, the CPU 102, the AU 110, or both are configured to execute one or more instructions (e.g., draw calls) such that a scene including one or more graphics objects is rendered. After rendering such a scene, the processing system 100 stores the scene in the storage 112, displays the scene on the display 130, or both. The display 130, for example, includes a cathode-ray tube (CRT) display, liquid crystal display (LCD), light emitting diode (LED) display, organic light emitting diode (OLED) display, or any combination thereof. To enable the processing system 100 to display a scene on the display 130, the I/O circuitry 114 includes display circuitry 148. The display circuitry 148, for example, includes high-definition multimedia interface (HDMI) connectors, DisplayPort connectors, digital visual interface (DVI) connectors, USB connectors, and the like, each including circuitry configured to communicatively couple the display 130 to the I/O circuitry 114. Additionally or alternatively, the display circuitry 148 includes circuitry configured to manage the display of one or more scenes on the display 130 such as display controllers, buffers, memory, or any combination thereof.

Further, the CPU 102, the AU 110, or both are configured to concurrently run one or more virtual machines (VMs), which are each configured to execute one or more corresponding applications. To manage communications between such VMs and the underlying resources of the processing system 100, such as any one or more components of processing system 100, including the CPU 102, the I/O device 108, the AU 110, and the system memory 106, the I/O circuitry 114 includes memory management unit (MMU) 146 and input-output memory management unit (IOMMU) 148. The MMU 150 includes, for example, circuitry configured to manage memory requests, such as from the CPU 102 to the system memory 106. For example, the MMU 150 is configured to handle memory requests issued from the CPU 102 and associated with a VM running on the CPU 102. These memory requests, for example, request access to read, write, fetch, or pre-fetch data residing at one or more virtual addresses (e.g., guest virtual addresses) each indicating one or more portions (e.g., physical memory addresses) of the system memory 106. Based on receiving a memory request from the CPU 102, the MMU 150 is configured to translate the virtual address indicated in the memory request to a physical address in the system memory 106 and to fulfill the request. The IOMMU 152 includes, for example, circuitry configured to manage memory requests (memory-mapped I/O (MMIO) requests) from the CPU 102 to the I/O device 108, the AU 110, or both, and to manage memory requests (direct memory access (DMA) requests) from the I/O device 108 or the AU 110 to the system memory 106. For example, to access the registers 144 of the I/O device 108, the registers 140 of the AU 110, and/or the AU memory 138, the CPU 102 issues one or more MMIO requests. Such MMIO requests each request access to read, write, fetch, or pre-fetch data residing at one or more virtual addresses (e.g., guest virtual addresses) which each represent at least a portion of the registers 144 of the I/O device 108, the registers 140 of the AU 110, or the AU memory 138, respectively. As another example, to access the system memory 106 without using the CPU 102, the I/O device 108, the AU 110, or both are configured to issue one or more DMA requests. Such DMA requests each request access to read, write, fetch, or pre-fetch data residing at one or more virtual addresses (e.g., device virtual addresses) which each represent at least a portion of the system memory 106. Based on receiving an MMIO request or DMA request, the IOMMU 152 is configured to translate the virtual address indicated in the MMIO or DMA request to a physical address and fulfill the request.

In variations, the processing system 100 can include any combination of the components depicted and described. For example, in at least one variation, the processing system 100 does not include one or more of the components depicted and described in relation to FIG. 1. Additionally, or alternatively, in at least one variation, the processing system 100 includes additional and/or different components from those depicted. The processing system 100 is configurable in a variety of ways with different combinations of components in accordance with the described techniques.

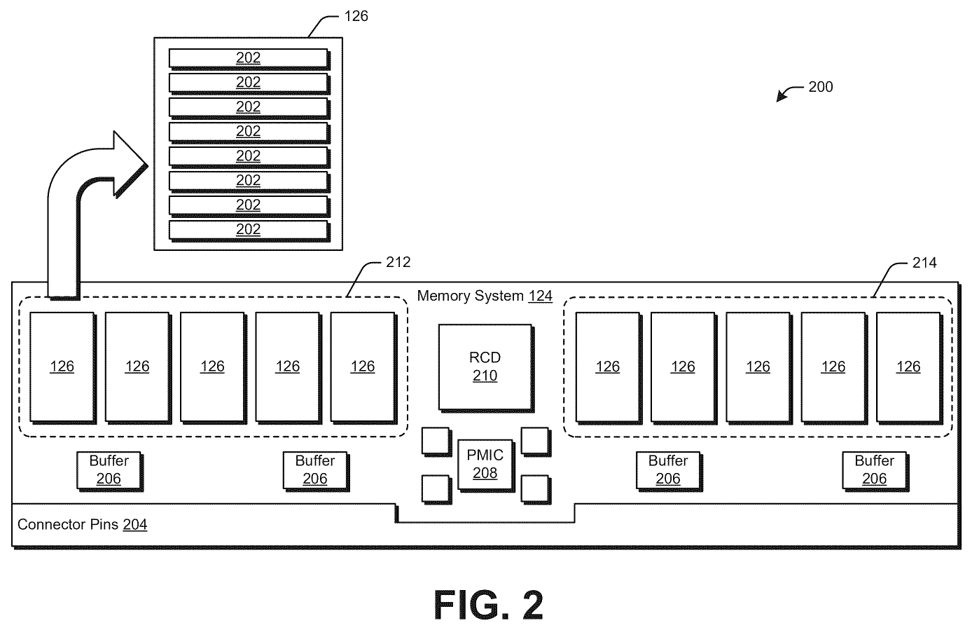

FIG. 2 is a block diagram of a non-limiting example 200 of a memory system. The illustrated example includes the memory system 124 having a plurality of the memory chips 126.

In one or more implementations, the memory system 124 is an in-line memory module, and each of the memory chips 126 is dynamic random-access memory (DRAM), such as synchronous dynamic random-access memory SDRAM. By way of example, the memory system 124 is a dual in-line memory module (DIMM). When configured as an in-line memory module, for instance, the memory system 124 includes the memory chips 126 (DRAMs) mounted communicably to a printed circuit board on one or both sides (i.e., front and/or back) of the printed circuit board. In one or more implementations, the memory system 124 is standardized, such that various aspects of the memory system 124 and/or the memory chips 126 conform to a standard, e.g., a JEDEC standard. Although ten memory chips 126 are depicted in the illustrated example, the memory system 124 can include any different integer number of memory chips 126 in accordance with the described techniques, e.g., two (2), eight (8), nine (9), twelve (12), fifteen (15), sixteen (16), twenty (20), twenty-four (24), twenty-seven (27), thirty (30), and so on.

In one or more implementations, at least one of the memory chips 126 includes a plurality of memory die 202, such as memory die arranged in a “stacked” or “3D” configuration. In connection with DRAM technology, such an arrangement may be referred to as “stacked DRAM,” “3D stacked DRAM,” or a “3D DRAM stack.” Thus, in one or more implementations, at least one of the memory chips 126 is a stacked DRAM. This also means that each of the memory chips 126 may comprise a stack of memory die 202 in at least one variation. For example, each of the memory chips 126 is a stacked DRAM. Although the view of the memory chips 126 with the stack of memory die 202 includes eight memory die, in variations, any of the memory chips 126 may have a different integer number of memory die, e.g., four (4), five (5), nine (9), ten (10), and so forth, without departing from the spirit or scope of the described techniques.

The memory system 124 also includes connector pins 204. The connector pins 204 serve as electrical connectors that are used to communicably link the memory system 124 to at least one other component of a system (e.g., of the system 100), allowing transfer over the link, for example, of data, address signals, power, control signals, command/address signals, and so on, between the memory system 124 and the rest of the system. In at least one implementation, the connector pins 204 electrically connect the memory system 124 to a motherboard or “host”. The connector pins 204 can include one or more of data transfer pins, address pins, power and ground pins, control pins, and error correcting code (ECC) pins, to name just a few. The memory system 124 may include varying integer numbers of the connector pins 204 arranged in various layouts (e.g., with double rows of pins, with offset pins, with notches or cutouts in the arrangement) and having any of a variety of shapes (e.g., rectangular, triangular, rounded rectangle, etc.), without departing from the described techniques. Additionally, the connector pins 204 may be formed of any of a variety of materials including, for example, gold and/or gold plating, which is a suitable conductor of electricity and is resistant to corrosion. In variations, one or more notches or cutouts may be present in the connector pins 204, e.g., on an outboard side of the memory system 124 resulting in a gap of space (not shown) between pins and/or on an inboard side of the memory system 124 resulting in a gap (not shown) filled with at least a portion of the printed circuit board (e.g., silicon and/or other components of a printed circuit board).

In this example, the memory system 124 is also depicted with buffer(s) 206, power management integrated circuit 208 (referred to as PMIC 208), and registered clock driver 210 (referred to as RCD 210). It is to be appreciated that in variations the memory system 124 includes different/additional components (e.g., one or more memory controllers), does not include one or more of the depicted and/or described components, includes different numbers of the depicted and/or described components (e.g., a different number of buffer(s) 206), and so on, without departing from the spirit or scope of the described techniques.

The buffer(s) 206 of the memory system 124 may include one or more types of buffers and/or buffers that perform any of a variety of functions for the memory system 124 (e.g., programmed to perform the different functions and/or configured in hardware to perform such different functions), such as data buffers, input buffers, output buffers, and so on. In one example, for instance, a buffer may be connected to two of the memory chips 126 on one side and to a system on chip (SoC) (e.g., the system 100) on the other side, enabling the memory chips 126 to communicate with the system in a time sequenced fashion. On a host side interface of the buffer to the system (e.g., an SoC), the buffer may effectively multiply a frequency up, doubling the bandwidth by having two devices (e.g., memory chips 126) on the other side of the buffer and supplying twice the data that is then serialized to the host (i.e., the system) at twice the speed.

In another example, a buffer may be programmed or otherwise configured to, in one direction of communication between the memory chips 126 (and/or one or more other components of the memory system 124) and one or more system components to which the memory system 124 is connected (e.g., a “host”), combine signals and/or data, and in an opposite direction of communication separate signals and/or data. For signals and/or data routed from the memory chips 126 to a host, for instance, at least one buffer(s) 206 may separate the signals and/or data for further transmission to the host. For signals and/or data routed in the opposite direction, e.g., from the host to the memory chips 126, though, the at least one buffer(s) 206 may combine the signals and/or data into one or more channels for further routing to the memory chips 126.

In one or more implementations, the memory system 124 is configured to support a multi-channel architecture, where the memory chips 126 are accessed over multiple channels of the architecture, e.g., over two or more channels. For example, a first group or cluster of the memory chips 126 is accessed over a first channel (e.g., Channel A), and a second group or cluster of the memory chips 126 is accessed over a second channel (e.g., Channel B). It is to be appreciated that the memory system 124 may support access over more than two channels, e.g., a third channel (e.g., Channel C), a fourth channel (e.g., Channel D), and so on.

While in some implementations an individual memory chip 126 is accessed over just one channel of the multiple channels (e.g., all the memory die 202 of the individual memory chip are accessed over the one channel), in variations, an individual memory chip 126 may be accessed over at least two of the multiple memory channels (e.g., a portion of the memory die 202 of the individual chip is accessed over a first channel and a different portion of the memory die 202 of the individual chip is accessed over a second channel). Alternatively or additionally, the memory system 124 supports a combination of such access, such that a first set of the memory chips 126 (at least one memory chip) is accessed entirely by a first channel, a second set of the memory chips 126 (at least one memory chip) is accessed entirely by a second channel, and a third set of the memory chips 126 (at least one memory chip) is accessed by both the first channel and the second channel (i.e., split access). In one or more implementations, such split access may be handled by a buffer 206 that is configured to facilitate access to the appropriate memory die of the memory chips 126 with the split access, such as for memory reads and/or memory writes. One or more of the memory chips 126 may be configured for such split access in scenarios where the memory system 124 is configured for error correcting code (ECC) use, for example. It is to be appreciated that access via multiple channels to the memory chips 126 may be implemented in a variety of ways for different numbers of channels, and include, for instance, one or more memory chips 126 that are accessed entirely over just one of the multiple channels and one or more memory chips 126 that are accessed over at least two of the channels (e.g., over at least a first channel and a second channel), without departing from the described techniques.

The illustrated example is depicted with an indication of a first cluster 212 of the memory chips 126 and an indication of a second cluster 214 of the memory chips 126. In at least one implementation, the first cluster 212 of the memory chips 126 is accessed over a first channel (and via respective buffer(s) 206 and connector pins 204), and the second cluster 214 of the memory chips 126 is accessed over a second channel (and via respective buffer(s) 206 and connector pins 204). For instance, read and write accesses of the first cluster 212 of memory chips 126 are serviced over the first channel, while read and write accesses of the second cluster 214 of memory chips 126 are serviced over the second channel. In at least one variation, while the memory chips 126 are physically clustered into multiple clusters, such physical clustering may not correspond to channels over which the memory chips 126 are accessed. Instead, for instance, despite being physically clustered on a printed circuit board, each of the memory chips 126 may be accessed over multiple channels (e.g., two channels), where one or more of the memory die 202 of an individual memory chip are accessed over a first channel, and one or more other memory die 202 of that same individual memory chip are accessed over at least one other channel.

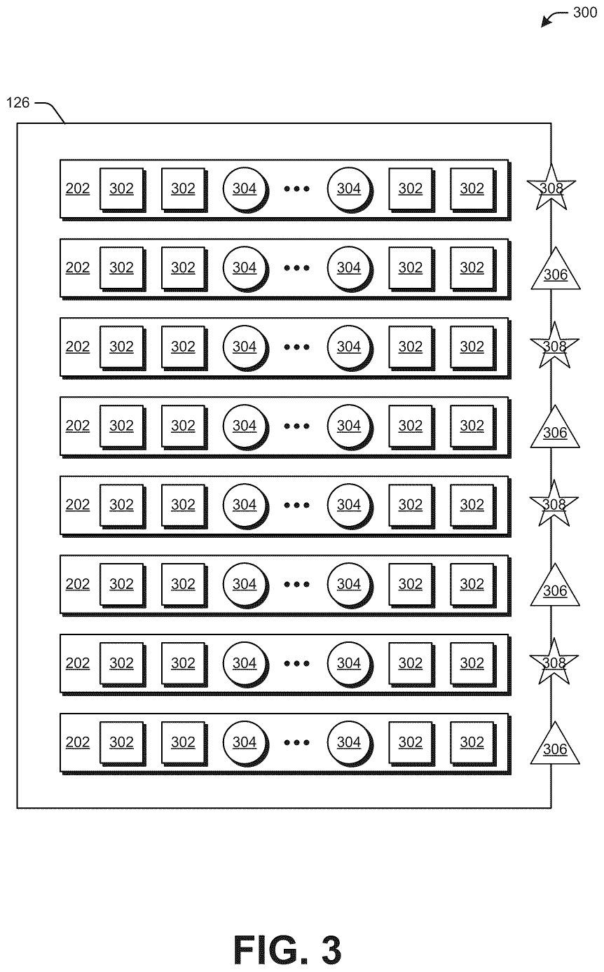

FIG. 3 is a block diagram of a non-limiting example 300 of pins of multiple memory die of a memory chip, such as of a stacked DRAM.

This figure depicts an example of one of the memory chips 126 having multiple memory die 202, such as when configured as a stacked DRAM. Here, each of the memory die 202 is shown with multiple types of pins 302, 304. As an example, the pins 302 correspond to data pins (DQ pins) and the pins 304 correspond to command/address pins (CA pins) of the memory die 202. In variations, the memory die 202 may have different numbers of pins, e.g., more pins or fewer pins. Additionally or alternatively, the memory die 202 may include different and/or additional types of pins (or pins configured for different functionality), examples of which include but are not limited to data strobe (DQS) pins, data mask (DM) pins, clock (CK) pins, chip select (CS) pins, and any other pin types used with memory.

In one or more implementations, the data (DQ) pins are bidirectional lines that transmit data during read memory accesses and write memory accesses, such as with a data strobe pin (DQS pin) acting as a strobe signal that indicates when the data on the DQ pins is valid. In other words, the data (DQ) pins are part of a memory interface, which allows data to be transferred to and from memory, such as on edges of a clock signal. As part of a DDR interface, for instance, the data (DQ) pins allow data to be transferred in connection with memory access requests (e.g., memory reads and memory writes) on both the rising and falling edges of the clock signal, doubling the effective data rate. In connection with a read memory request, the memory die 202 send data stored therein out on the data (DQ pins), and the DQS signal indicates when the data is valid. In connection with a write memory request, a memory controller (e.g., a buffer within the memory chip 126 package or an external controller) sends data on the data (DQ) pins to be written to the memory die 202, and the DQS signal indicates when the data is valid for the memory die 202 to latch.

The pins 302, 304 may be connected in a variety of ways to enable data to be read from and written to the memory die 202. In one or more implementations, the memory die 202 belong to or are otherwise associated with ranks, e.g., rank zero (R0) or rank one (R1). Broadly, the ranks define a set of DRAM memory die that are connected to a same chip select and can therefore be accessed simultaneously. The illustrated example includes a first indication 306 and a second indication 308, which may represent a first rank (rank zero—R0) and a second rank (rank one—R1), respectively. In the illustrated example, the inclusion of these ranks indicates one possible division of the memory die 202 between the different ranks. In variations, the memory die 202 may be divided differently among ranks. Alternatively or additionally, there may be a different number of ranks than two, such as one rank, three ranks, and so on.

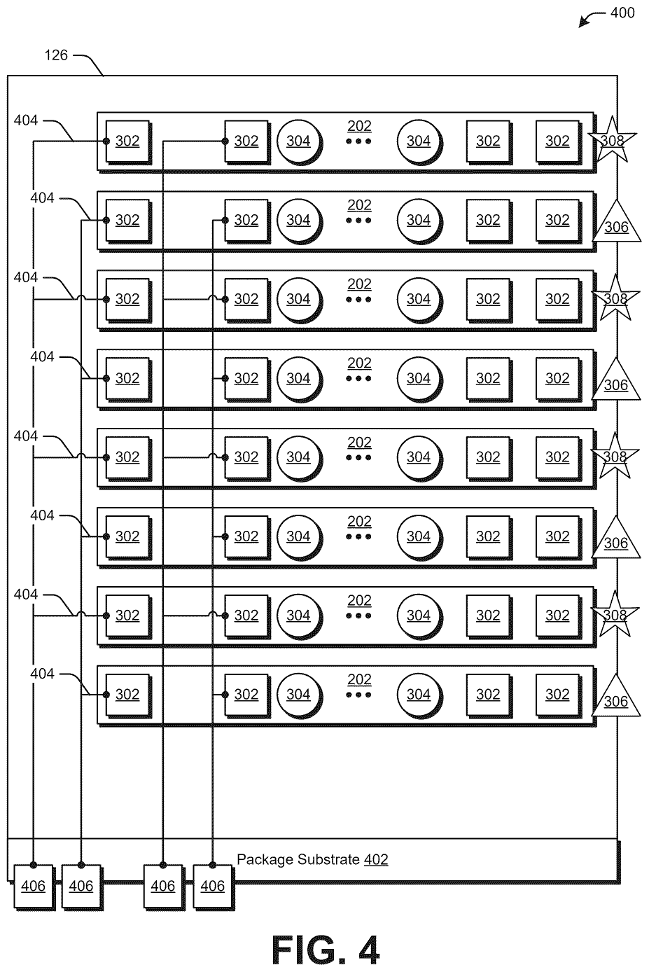

FIG. 4 is a block diagram of a non-limiting example 400 depicting how data (DQ) pins of multiple memory die of a memory chip are directly connected to a package substrate.

The illustration depicts an example of one of the memory chips 126 having multiple memory die 202, such as when configured as a stacked DRAM. Like in the example discussed above, each of the memory die 202 has a plurality of pins 302, 304. In this example, the pins 302 correspond to data (DQ) pins of the memory chip 126. Notably, each of the data (DQ) pins of a first column and second column of pins is connected (e.g., directly) to a package substrate 402 of the memory chip 126 via a respective connector 404. In at least one implementation, each data (DQ) pin of every memory die 202 is connected via a respective connector 404 to the package substrate 402. In at least one implementation, the connectors 404 are connected to pins of the package substrate 402. Due to the individual connections, the described techniques may utilize twice as many pins of the package substrate as conventional approaches, since each data (DQ) pin is connected.

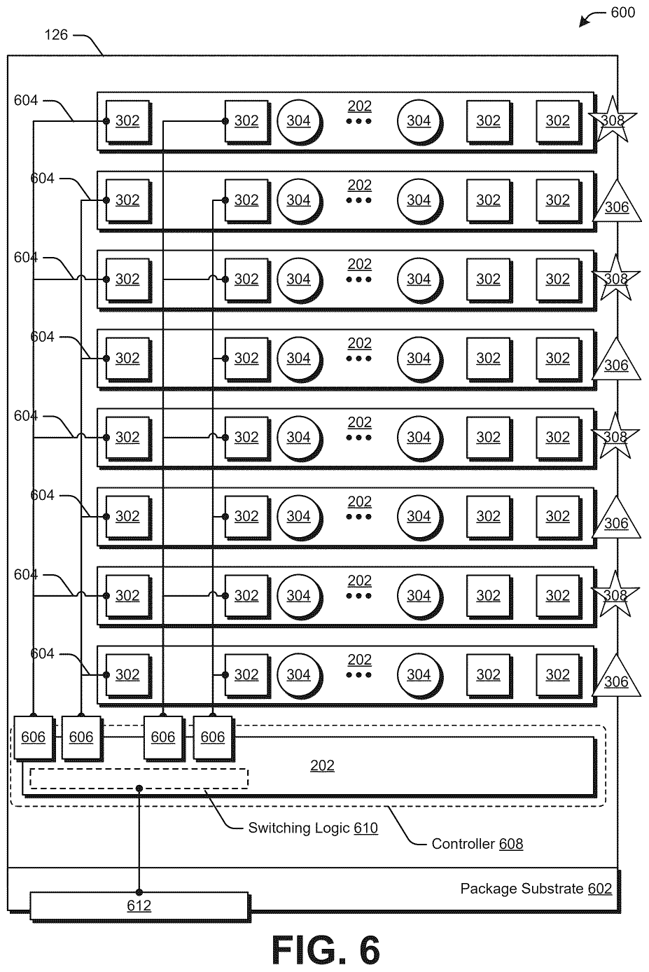

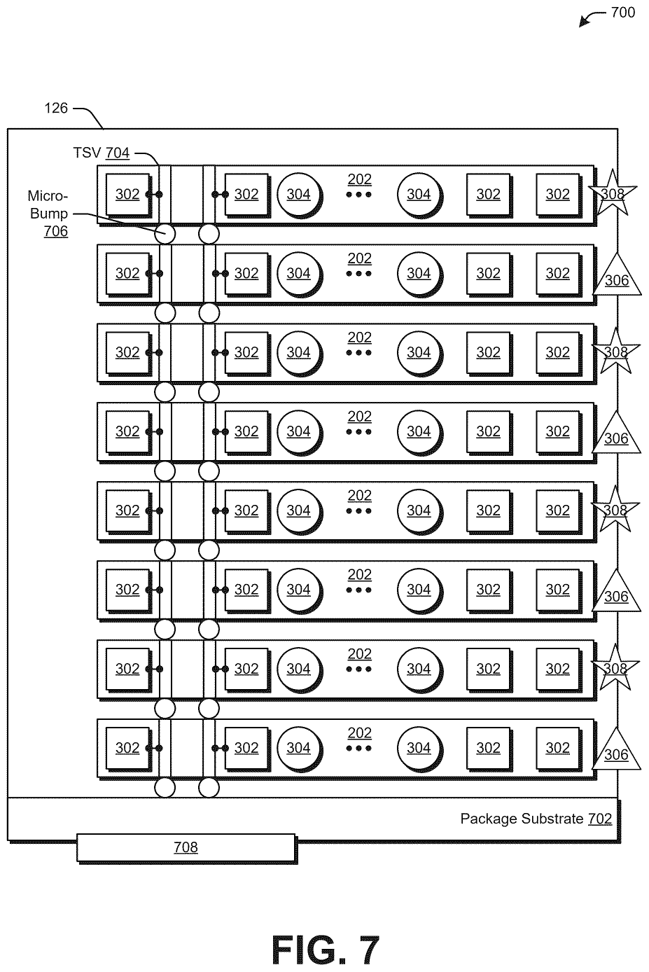

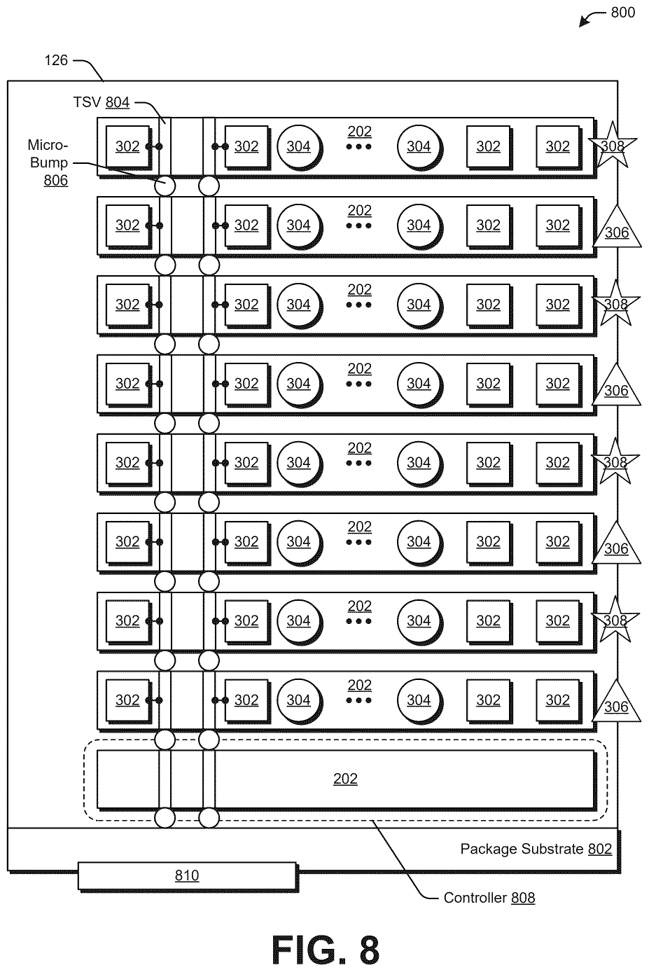

In at least one implementation, the connectors 404 are bond wires, such that there is a bond wire connecting each data (DQ) pin of the memory chip 126 to the package substrate 402. Said another way, each data (DQ) pin is “bonded” to the package substrate 402. In at least one variation, one or more of the data (DQ) pins (e.g., all of them) are instead bonded externally at the printed circuit board level, e.g., externally to the printed circuit board of the memory system 124. The data (DQ) pins (and/or other pins) of the memory die 202 may be connected to the package substrate 402, and/or a buffer (or other component(s)) integrated between the pins and the package substrate 402 (e.g., a memory die 202 of the memory chip 126), using any of a variety of connections in addition to or alternatively from bond wires, examples of which include but are not limited to micro bumps, flip-chip solder (e.g., C4) bumps, and copper to copper bonding, to name just a few. Examples of connecting the data (DQ) pins 302 of the memory die 202 to an intermediate component (e.g., another memory die 202) which serves as a controller to route signals to appropriate data (DQ) pins 302 are discussed in relation to FIG. 6 and FIG. 8. Examples utilizing different types of connections to a package substrate (e.g., TSVs and micro bumps) are discussed in relation to FIG. 7 and FIG. 8.

In the illustrated example, the memory chip 126 is also depicted having data package entry points 406, e.g., ball grid array (BGA) balls. In one or more implementations, the data package entry points 406 serve as an interface between the memory chip 126 package and an external component, such as a printed circuit board (PCB) and/or memory system (e.g., memory module). In implementations where the data package entry points 406 are BGA balls, the BGA balls are mounted to the package substrate and act as a first contact point of the memory chip 126 package for data lines. Incoming and outgoing signals can be split and combined in any of a variety of ways (e.g., using a buffer and/or memory die 202 serving as a controller), enabling access to the data (DQ) pins 302 of the memory chip 126 individually. Due to this, a number of data package entry points 406 on the package substrate 402 can differ from a number of connectors between the data (DQ) pins 302 and the package substrate 402 (and/or between the data (DQ) pins and an intermediate component serving as a controller). Although four data package entry points 406 are depicted, in at least one variation, a memory chip can include only one data package entry point without departing from the spirit or scope of the described techniques.

This connection scheme contrasts with conventional approaches where pairs of data (DQ) pins are connected to one another via short bond wires between memory die, such as where a data (DQ) pin of a first die associated with a first rank is connected with a short bond wire to a data (DQ) pin of a second, neighboring die associated with a second rank. In some conventional approaches, each of the data pins is paired with another data pin, such as by using a short bond wire, and then the data from the pair of data pins may be communicated externally at the printed circuit board level or to the package substrate. Rather than short bonds between pairs of data (DQ) pins, the data (DQ) pins of the memory chip 126 are individually connected with connectors 404 forming long bonds (e.g., long bond wires) to the package substrate 402 or externally at the printed circuit board level.

As discussed in relation to FIG. 6 and FIG. 8 below, in one or more implementations, the memory chip 126 includes an intermediate component disposed within a package of the memory chip 126, at least in terms of electrical connectivity, between the data (DQ) pins and the package pins or the data package entry points 406 to route signals to the data (DQ) pins individually. For instance, the connectors 404 connect the data (DQ) pins to the intermediate component, which is then connected to the package substrate 402 via any of a variety of connections, e.g., bond wires, pins, BGA balls, micro bumps, solder (e.g., C4) bumps, copper to copper bonding, and so on. Additionally or alternatively, the data (DQ) pins of the memory die 202 are individually connected to such an intermediate component using any of a variety of connections, including but not limited to bond wires, micro bumps, pins, solder (e.g., C4) bumps, copper to copper bonding, and so forth.

In this configuration, the intermediate component may be programmable or otherwise configurable at the memory chip 126 package level to control use of the memory chip 126's data (DQ) pins in different manners rather than be controlled outside the package. As depicted in the illustrated examples, at least one of the memory die 202 (e.g., a DRAM base die in the stack) is configured to act like a controller to control and electrically isolate the data (DQ) signals, e.g., rather than using a separate buffer between the memory die 202 and the package substrate 402. Alternatively or additionally, a compute unit may be used for this purpose. In at least one implementation, such an intermediate component, capable of controlling and/or electrically isolating such signals, is configured to handle respective clocking signals for the memory system 124, such as data strobe (DQS), write clock (WCK), and clock (CK). The DQS, WCK, CK, and/or whatever other data (DQ) or command address (CA) clocking mechanism may also be configurable in variations

Multi-die memory chips with individually connected data (DQ) pins provide significant advantages over conventional approaches. In contrast to traditional stacked DRAM configurations where pairs of data pins from memory die having different ranks are connected together using short bond wires, the described architecture may connect each individual data pin directly to a package substrate of the memory chip or externally at the printed circuit board level, e.g., using long bond wires.

This direct, individual connection scheme for data pins enables several key benefits. For example, it allows for increased flexibility in memory access configurations. The memory chip can be used, for instance, in a multiplexed (MUX) mode and/or an error correcting code (ECC) mode. Further, signal integrity is improved by eliminating the need for short bonds between die, which can introduce signal degradation. Memory bandwidth and system performance can also be enhanced by allowing separate access to each memory rank within the multi-die package.

As mentioned above, the memory chip comprises a plurality of memory die arranged in a stacked configuration, a package substrate, and a plurality of data pins. Crucially, each data pin is individually connected to the package substrate, or an intermediate component within the package between the pins and the package substrate, via a respective connector, such as a bond wire or any of the variety of connectors enumerated above. Often, memory die are separated into at least two ranks, with subsets of data pins associated with different ranks. By making these subsets of data pins individually accessible in the described architecture, the memory chip gains the flexibility to operate in various modes like multiplexed or error correcting code modes.

This architecture represents a departure from conventional systems where data pins are interconnected between die. By providing direct, individual connections to the package substrate, the described approach overcomes limitations in flexibility and potential performance inherent in traditional stacked DRAM configurations. The result is a memory chip that offers greater versatility, improved signal integrity, and the potential for enhanced bandwidth and overall system performance.

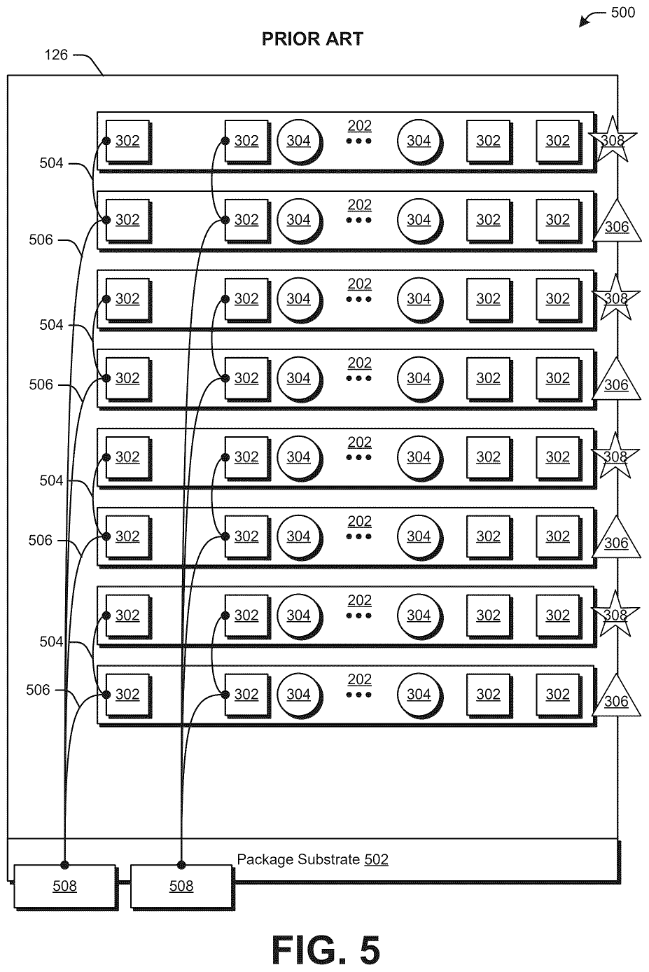

FIG. 5 depicts a prior art example 500 of connecting data pins of a multi-die memory chip to data package entry points.

In the prior art example 500, the memory chip 126 includes multiple memory die 202 arranged in a stacked configuration on a package substrate 502. Each memory die 202 includes data pins 302 and command address pins 304. The memory die 202 are organized into different ranks, as indicated by the alternating first indications 306 and second indications 308 positioned along the right side of the illustration.

In this conventional approach, the data pins 302 are interconnected using short connectors 504 that connect pairs of data pins between adjacent memory die 202 of different ranks. For example, a data pin 302 from a memory die 202 associated with a first rank is shown connected via a short connector 504 to a corresponding data pin 302 from a neighboring memory die 202 associated with a second rank. These short connectors 504 may be implemented as short bond wires that create direct electrical connections between the paired data pins of adjacent memory die 202.

In addition to the short connectors 504, the prior art example 500 depicts long connectors 506 extending from paired data pins to data package entry points 508 on the package substrate 502. Such long connectors 506 may be implemented as long bond wires that route the combined signals from the paired data pins to external connection points. The data package entry points 508 serve as interfaces between the memory chip 126 package and external components, such as a printed circuit board or memory system.

Such prior art configurations limit flexibility in memory access because the paired data pins 302 cannot be accessed independently. When a memory access request is received, both data pins 302 in a pair are activated simultaneously, preventing individual control of data pins from different ranks. Additionally, the short connectors 504 between memory die 202 may introduce signal degradation and limit the potential for improved signal integrity. This conventional approach also restricts the ability to configure the memory chip 126 for different operational modes, such as switching between multiplexed and error correcting code modes, since the data pins are permanently paired through the short connectors 504 and unable to be accessed individually.

FIG. 6 is a block diagram of a non-limiting example 600 depicting how data (DQ) pins of multiple memory die of a memory chip are directly connected to a die serving as a controller for the memory chip.

In the illustrated example 600, the memory chip 126 includes multiple memory die 202 arranged in a stacked configuration on a package substrate 602. Each memory die 202 includes data pins 302 and command address pins 304. In one or more implementations, the memory die 202 can be organized into different ranks as illustrated with the alternating first indications 306 and second indications 308.

In this implementation, each data pin 302 of the memory die 202 is individually connected to a controller 608 via respective connectors 604. In at least one implementation, the connectors 604 are bond wires that provide direct electrical connections between individual data pins 302 and controller connection points 606 on the controller 608. In variations, the connectors 604 may be implemented using other types of connections, as described above and below.

The controller 608 comprises an additional memory die 202 within the memory chip 126 package that serves as an intermediate component for routing data signals. For example, the controller 608 includes switching logic 610 that enables selective routing of data signals to and from individual data pins 302 of the stacked memory die 202. In one or more implementations, the switching logic 610 is or includes multiplexer circuitry that can direct data signals from external sources to specific data pins 302 during write operations, or route data signals from specific data pins 302 to external destinations during read operations.

In one or more implementations, any of the memory die 202 within the stacked configuration may be designated or configured to serve as the controller 608. For instance, a memory die 202 positioned at the bottom of the stack (such as a base die), in the middle of the stack, or at the top of the stack may be selected and programmed to function as the controller 608 with the switching logic 610. This flexibility allows the memory chip 126 to optimize performance based on specific design requirements or manufacturing considerations, as different memory die 202 positions within the stack may offer varying advantages for signal routing and thermal management.

In one or more implementations, the controller 608 connects to the package substrate 602 and communicates with external components through data package entry points 612. This configuration allows the controller 608 to manage access to individual data pins 302 independently, rather than accessing paired data pins simultaneously as in conventional approaches. The switching logic 610 may be programmable or configurable to support different operational modes, such as multiplexed mode or error correcting code mode, by selectively routing data signals to appropriate subsets of data pins 302, such as the data pins associated with different ranks.

By utilizing the controller 608 with the switching logic 610, the memory chip 126 can provide flexible access to individual data pins 302 while maintaining signal integrity through the individual connectors 604. This approach enables independent control of data pins from different ranks and supports various memory access configurations that may enhance system performance and bandwidth utilization.

FIG. 7 is a block diagram of a non-limiting example 700 depicting how data (DQ) pins of multiple memory die of a memory chip are connected to a package substrate with through silicon vias and micro-bumps.

In the illustrated example 700, the memory chip 126 includes multiple memory die 202 arranged in a stacked configuration on a package substrate 702.

In this implementation, the data pins 302 of the memory die 202 are individually connected to the package substrate 702 using through silicon vias (TSVs) 704 and micro bumps 706. The TSVs 704 extend vertically through the stacked memory die 202, providing electrical pathways that traverse through the silicon substrate of each die. These TSVs 704 enable direct electrical connections between data pins 302 on different layers of the stack and facilitate routing of signals through the vertical structure of the memory chip 126.

The micro bumps 706 serve as connection interfaces between adjacent memory die 202 and between the memory die 202 and the package substrate 702. In one or more implementations, the micro bumps 706 are small solder connections that provide mechanical support and electrical connectivity. The micro bumps 706 may be positioned at regular intervals across the surface of each memory die 202 to establish reliable connections with corresponding contact points on adjacent die or the package substrate 702.

The combination of TSVs 704 and micro bumps 706 enables each data pin 302 to be individually accessible through the package substrate 702, similar to the bond wire approach described in previous examples but using a different connection methodology. This TSV and micro bump configuration may offer advantages in terms of connection density, signal integrity, and manufacturing scalability compared to traditional bond wire approaches.

Data package entry points 708 are positioned on the package substrate 702 to provide external connectivity for the memory chip 126. The TSVs 704 and micro bumps 706 route signals from individual data pins 302 through the stacked configuration to these data package entry points 708, enabling external access to each data pin 302 independently.

This configuration maintains the individual accessibility of data pins 302 from different ranks while utilizing advanced packaging technologies. Additionally, this approach may enable higher connection densities and more compact package designs while preserving the flexibility benefits of individual data pin access.

FIG. 8 is a block diagram of a non-limiting example 800 depicting how data (DQ) pins of multiple memory die of a memory chip are connected to a die serving as a controller for the memory chip with through silicon vias and micro-bumps.

In the illustrated example 800, the memory chip 126 includes multiple memory die 202 arranged in a stacked configuration on a package substrate 802. In this implementation, the data pins 302 of the memory die 202 are individually connected to a controller 808 using through silicon vias (TSVs) 804 and micro bumps 806. The TSVs 804 extend vertically through the stacked memory die 202, providing electrical pathways that traverse through the silicon substrate of each die. These TSVs 804 enable direct electrical connections between data pins 302 on different layers of the stack and the controller 808, facilitating routing of signals through the vertical structure of the memory chip 126.

The micro bumps 806 serve as connection interfaces between adjacent memory die 202 and between the memory die 202 and the controller 808. The controller 808 comprises an additional memory die 202 within the memory chip 126 package that serves as an intermediate component for routing data signals. Similar to the controller 608 described in relation to FIG. 6, the controller 808 may include switching logic that enables selective routing of data signals to and from individual data pins 302 of the stacked memory die 202. In one or more implementations, this switching logic may include multiplexer circuitry that can direct data signals from external sources to specific data pins 302 during write operations, or route data signals from specific data pins 302 to external destinations during read operations.

The combination of TSVs 804, micro bumps 806, and the controller 808 enables each data pin 302 to be individually accessible while utilizing advanced packaging technologies. This configuration may offer advantages in terms of connection density, signal integrity, and manufacturing scalability compared to traditional bond wire approaches while maintaining the flexibility benefits of individual data pin access.

The controller 808 connects to the package substrate 802 and communicates with external components through data package entry points 810. Data package entry points 810 are positioned on the package substrate 802 to provide external connectivity for the memory chip 126. The TSVs 804 and micro bumps 806 route signals from individual data pins 302 through the stacked configuration to the controller 808, which then manages communication with these data package entry points 810, enabling external access to each data pin 302 independently.

This configuration maintains the individual accessibility of data pins 302 from different ranks while combining the benefits of advanced packaging technologies with intelligent signal routing. The controller 808 may be programmable or configurable to support different operational modes, such as multiplexed mode or error correcting code mode, by selectively routing data signals to appropriate subsets of data pins 302 through the TSV 804 and micro bump 806 connections.

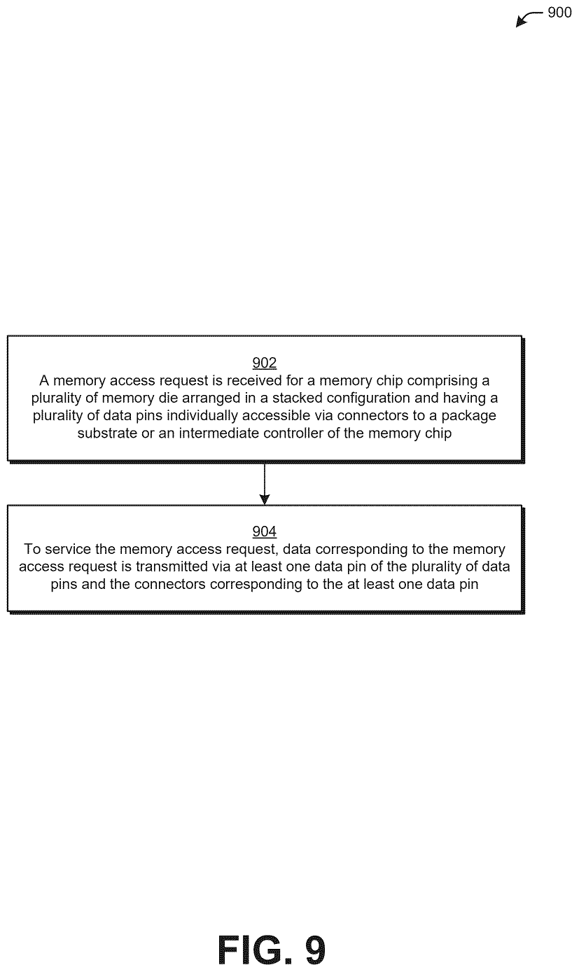

FIG. 9 depicts a procedure 900 in an example implementation of a multi-die memory chip with individually connected data (DQ) pins.

A memory access request is received for a memory chip comprising a plurality of memory die arranged in a stacked configuration and having a plurality of data pins individually accessible via connectors to a package substrate or an intermediate controller of the memory chip (block 902). In one or more implementations, each data pin of the plurality of data pins is individually connected to the package substrate or intermediate controller via a respective connector, such as a bond wire. By way of example, a memory access request is received for the memory chip 126. This memory access request may be for accessing the plurality of memory die 202 of the memory chip 126. Examples of memory access requests that utilize the data (DQ) pins include read requests and write requests. As discussed above, the plurality of memory die 202 are arranged in a stacked configuration within the memory chip 126, and the plurality of data pins 302 are connected to the package substrate 402 or an intermediate controller (such as an intermediate memory die 202 serving as a controller) via connectors 404, such that the data pins are individually accessible simultaneously.

To service the memory access request, data corresponding to the memory access request is transmitted via at least one data pin of the plurality of data pins and corresponding connectors of the at least one data pin (block 904). By way of example, data corresponding to the memory access request which is received at block 902 is further transmitted via at least one of the data pins 302 and the connectors 404 which correspond to the at least one data pin 302. This transmission may involve sending data from the package substrate 402 or the intermediate controller to one or more of the memory die 202 in the case of a write operation, or sending data from one or more of the memory die 202 to the package substrate 402 or the intermediate controller in the case of a read operation.

In scenarios where the memory access request is a write request, the data corresponding to the memory access request is transmitted from the package substrate 402 or the intermediate controller via corresponding connectors 404 to the at least one data pin 302 and sent on the at least one data pin 302 for writing to the memory die 202. Alternatively, when the memory access request is a read request, the data is read from a location in the memory chip 126 and sent on the at least one data pin 302 via corresponding connectors 404 to the package substrate 402 or the intermediate controller. This flexibility in data transmission allows for efficient handling of both read and write operations, leveraging individual connections between each data pin 302 and the package substrate 402 or the intermediate controller. Connections enabling individual data pin access may enable faster data transfer and reduced signal interference compared to conventional approaches.

It is to be appreciated that the figures are not drawn to scale in the illustrated examples, and the various shapes used in the figures to represent various components may differ (perhaps significantly) from the actual shapes of those components in implementation.

What is claimed is:

1. A memory chip, comprising:
a package substrate; and
a plurality of memory die arranged in a stacked configuration, the plurality of memory die having a plurality of data pins, wherein the plurality of data pins are individually accessible via connectors to the package substrate or an intermediate controller.

2. The memory chip of claim 1, wherein the connectors are bond wires.

3. The memory chip of claim 1, wherein the connectors include through silicon vias and micro bumps.

4. The memory chip of claim 1, wherein each data pin of the plurality of data pins is individually connected to the package substrate or the intermediate controller via a respective connector.

5. The memory chip of claim 1, wherein the intermediate controller is a memory die of the plurality of memory die configured to control routing of data to and from each of the plurality of data pins individually.

6. The memory chip of claim 5, wherein the memory die is further configured to isolate data signals and handle clocking signals including at least one of data strobe (DQS), write clock (WCK), or clock (CK) signals.

7. The memory chip of claim 1, wherein the plurality of memory die are separated into at least two ranks.

8. The memory chip of claim 7, wherein a first subset of the plurality of data pins is associated with a first rank and a second subset of the plurality of data pins is associated with a second rank.

9. The memory chip of claim 8, wherein the first subset of data pins and the second subset of data pins are individually accessible.

10. The memory chip of claim 1, wherein the intermediate controller is a buffer connectively disposed between the plurality of data pins and the package substrate, and wherein each data pin of the plurality of data pins is connected to the buffer via the connectors and the buffer is connected to the package substrate.

11. The memory chip of claim 10, wherein the buffer is configured to control the plurality of data pins individually to transmit data in association with performing at least one of a read memory access or a write memory access of the plurality of memory die.

12. The memory chip of claim 1, wherein the plurality of data pins are individually controllable by a buffer external to the memory chip to transmit data in association with performing at least one of a read memory access or a write memory access of the plurality of memory die.

13. The memory chip of claim 1, wherein the memory chip is a dynamic random-access memory (DRAM) package and the plurality of memory die are DRAM die.

14. A method comprising:
receiving a memory access request for a memory chip comprising a plurality of memory die arranged in a stacked configuration and having a plurality of data pins individually accessible via connectors to a package substrate or an intermediate controller of the memory chip; and
causing data corresponding to the memory access request to be transmitted via at least one data pin of the plurality of data pins and the connectors corresponding to the at least one data pin to service the memory access request.

15. The method of claim 14, wherein the memory access request is a write request.

16. The method of claim 15, further comprising causing the data corresponding to the memory access request to be transmitted from the package substrate via the connectors corresponding to the at least one data pin and sent on the at least one data pin for writing.

17. The method of claim 14, wherein the memory access request is a read request.

18. The method of claim 17, further comprising causing the data to be read from a location in the memory chip where the data is stored and sent on the at least one data pin via the connectors corresponding to the at least one data pin to the package substrate.

19. A computing system, comprising:
a processor; and
a memory system communicatively coupled to the processor to service memory access requests of the processor, wherein the memory system includes a memory chip comprising:
a package substrate; and
a plurality of memory die arranged in a stacked configuration, the plurality of memory die having a plurality of data pins, wherein the plurality of data pins are individually accessible via connectors to the package substrate or an intermediate controller.

20. The computing system of claim 19, wherein the memory system is an in-line memory module.
